(19) United States
(12) Patent Application Publication
(10) Pub. No.: US 2008/0109691 A1
(43) Pub. Date: May 8, 2008

(54) Method and Apparatus for Executing a BIST Routine

(76) Inventors: James Norris Dieffenderfer, Apex, NC (US); Anand Krishnamurthy, Cary, NC (US); Clint Wayne Mumford, Apex, NC (US); Thomas Philip Speier, Holly Springs, NC (US)

Correspondence Address: QUALCOMM Incorporated;Patent Department, 5775 Morehouse Drive, San Diego, CA, 92121-1714, US

(21) Appl. No.: 11/553,582

(22) Filed: Oct. 27, 2006

(51) Int. Cl. G01R 31/28

(52) U.S. Cl. 714/733

(57) ABSTRACT

During a Built-In Self-Test (BIST) routine, execution of a sequence of tests is re-initiated after a corrective action is taken starting with the test having the highest re-ordered priority. The test having the highest re-ordered priority corresponds to a test in a sequence of tests that detected the error corresponding to the corrective action taken or a related test in the case where the test that detected the error is dependent upon results generated by the related test. According to one embodiment, a BIST routine is executed by initiating execution of a sequence of tests configured to detect errors and, after a corrective action is taken in response to one or more of the errors being detected, re-initiating execution of the sequence of tests starting with the test that detected the error corresponding to the corrective action most recently taken.

### BACKGROUND

1. Field of the Invention

The present invention generally relates to Built-In Self-Test (BIST), and particularly relates to re-executing a sequence of tests during a BIST routine after taking a corrective action.

2. Relevant Background

Built-In Self-Test (BIST) is a methodology that enables a device such as an integrated circuit, board or system to test itself. Built-in test equipment, hereinafter referred to as a BIST engine, includes hardware and/or software incorporated into a device to provide BIST capability. BIST may be used to test memory, digital logic, analog, or mixed-signal portions of an integrated circuit. Conventional BIST engines comprise a test pattern generator, an output-response analyzer and a BIST state machine. Under control of the BIST state machine, the output-response analyzer observes the response of a device to a sequence of tests generated by the test pattern generator. If the device's response matches an expected response, then it passes the BIST routine. Otherwise, the device fails.

A device may fail a BIST routine for various reasons. For example, a device may fail due to a ‘hard’ or ‘soft’ failure mechanism. A ‘hard failure’ is a term of art that refers to a fault having a permanent failure signature such as a ‘stuck-at’ fault (e.g., stuck-at one or stuck-at zero fault). Conversely, a ‘soft failure’ is a term of art that refers to a fault having an intermittent failure signature, e.g., a fault caused by sensitivity to an operating parameter such as voltage, temperature or operating frequency. As such, a hard failure occurs across a range of operating parameters while a soft failure does not. That is, a soft failure may be obviated by adjusting a particular operating parameter. Regardless of the failure signature, BIST provides a mechanism for self-identifying faulty circuitry.

Some conventional devices have redundant elements for repairing faulty circuitry. For example, a memory device may include one or more redundant array lines for replacing faulty array lines. In another example, redundant logic circuits may be available for repairing faulty logic circuits. In response to a fault being detected by a BIST engine, the faulty circuitry is replaced with a corresponding redundant element if the fault is repairable. Otherwise, the circuit is discarded.

If an identified fault is repairable, a conventional BIST engine re-executes the same sequence of tests it initially executed to detect the fault, thus verifying whether the corrective action taken fixed the fault. The sequence of tests is conventionally re-executed in the same order after a corrective action is taken. That is, a conventional BIST engine re-executes a sequence of tests in the same predetermined, fixed order regardless of where a test that detected a repairable fault is positioned in the sequence of tests. As such, the sequence of tests is conventionally re-executed starting with the first test in the sequence regardless of which test detected a repairable fault.

### SUMMARY OF THE DISCLOSURE

According to the methods, apparatus and computer program product taught herein, execution of a sequence of tests during a Built-In Self-Test (BIST) routine is re-initiated after a corrective action is taken starting with the test having the highest re-ordered priority. The test having the highest re-ordered priority corresponds to a test in a sequence of tests that detected the error corresponding to the corrective action taken or a related test in the case where the test that detected the error is dependent upon results generated by the related test. As such, the efficiency of BIST routines is improved by skipping unnecessary re-execution of certain tests.

According to one embodiment, a BIST engine comprises circuitry configured to initiate execution of a sequence of tests configured to detect errors and, after a corrective action is taken in response to one or more of the errors being detected, to re-initiate execution of the sequence of tests starting with the test that detected the error corresponding to the corrective action most recently taken. In one embodiment, an identifier uniquely associated with the test that detected the most recent error is stored. As such, the circuitry is configured to re-initiate execution of the sequence of tests by directing retrieval of the identifier and re-initiating execution of the sequence of tests starting with the test indicated by the identifier.

According to one embodiment of computer program product for directing execution of a BIST routine in an integrated circuit, the computer program product comprises program code for initiating execution of a sequence of tests. The computer program product also includes program code for re-initiating execution of the sequence of tests after a corrective action is taken starting with the test having a highest re-ordered priority.

Of course, the present invention is not limited to the above features and advantages. Those skilled in the art will recognize additional features and advantages upon reading the following detailed description, and upon viewing the accompanying drawings.

### BRIEF DESCRIPTION OF DRAWINGS

FIG. 1 is a block diagram illustrating an embodiment of a Built-In Self-Test (BIST) engine.

FIG. 2 is a logic flow diagram illustrating an embodiment of program logic for executing a BIST routine by the BIST engine of FIG. 1.

FIG. 3A is timing diagram illustrating execution of a sequence of tests by a conventional BIST engine that detects a single correctable error.

FIG. 3B is timing diagram illustrating execution of a sequence of tests by the BIST engine of FIG. 1 that detects a single correctable error.

FIG. 4A is timing diagram illustrating execution of a sequence of tests by a conventional BIST engine that detects two correctable errors.

FIG. 4B is timing diagram illustrating execution of a sequence of tests by the BIST engine of FIG. 1 that detects two correctable errors.

FIG. 5 is a block diagram illustrating an embodiment of a microprocessor including the BIST engine of FIG. 1.

### DETAILED DESCRIPTION

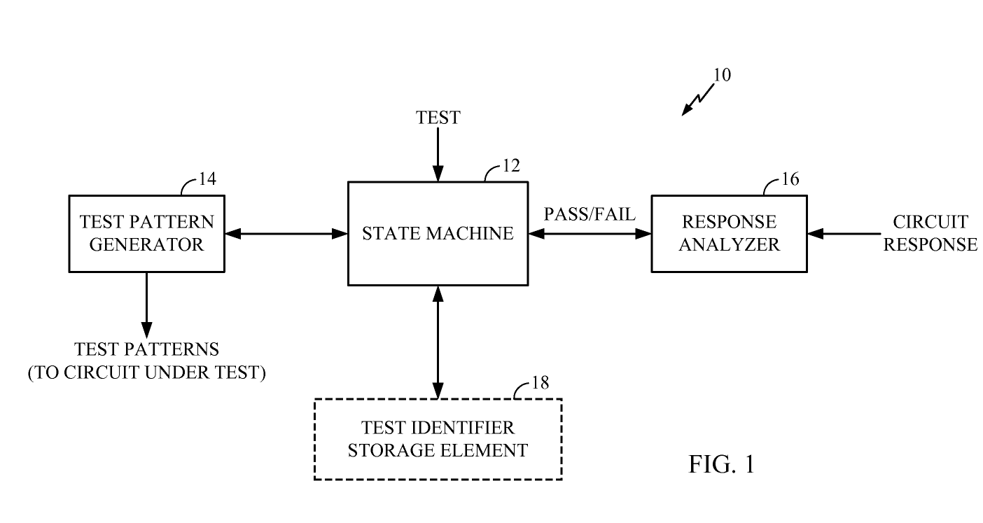

FIG. 1 illustrates an embodiment of a Built-In Self-Test (BIST) engine 10 having a state machine 12, a test pattern generator 14 and a response analyzer 16. The BIST engine 10 provides a sequence of tests, e.g., as generated by the test pattern generator 14, to a circuit under test (not shown). The response analyzer 16 compares an expected response with the response of the circuit under test to the test sequence. If the circuit's response matches the expected response, the response analyzer 16 generates a pass indication. Otherwise, the response analyzer 16 indicates that the test sequence detected an error.

If a correctable error is detected, a corresponding corrective action is taken in an attempt to fix the error. Upon completion of the corrective action, the BIST engine 10 verifies whether the fault was successfully corrected. However, instead of re-initiating execution of the test sequence in its original order, the state machine 12 re-initiates execution of the test sequence starting with the test having the highest re-ordered priority, i.e., the test that detected the correctable error or a related test in the case where the test that detected the correctable error is dependent upon results generated by the related test. To that end, a storage element 18 included in or associated with the BIST engine 10 stores an identifier uniquely associated with each test that detects an error, e.g., a test index or ID that uniquely identifies tests that detect an error. The storage element 18 may be volatile such as a register, static random access memory, etc. or non-volatile such as FLASH memory, magnetic random access memory or the like. Regardless, when the state machine 12 re-initiates execution of the test sequence after a corrective action has been taken, it directs access to the storage element 18 for retrieval of the corresponding test identifier. The test identified by the retrieved identifier, that is the test that detected the error causing the most recently taken corrective action (or a related test), is re-executed first by the BIST engine 10, thus enabling a more efficient use of BIST resources.

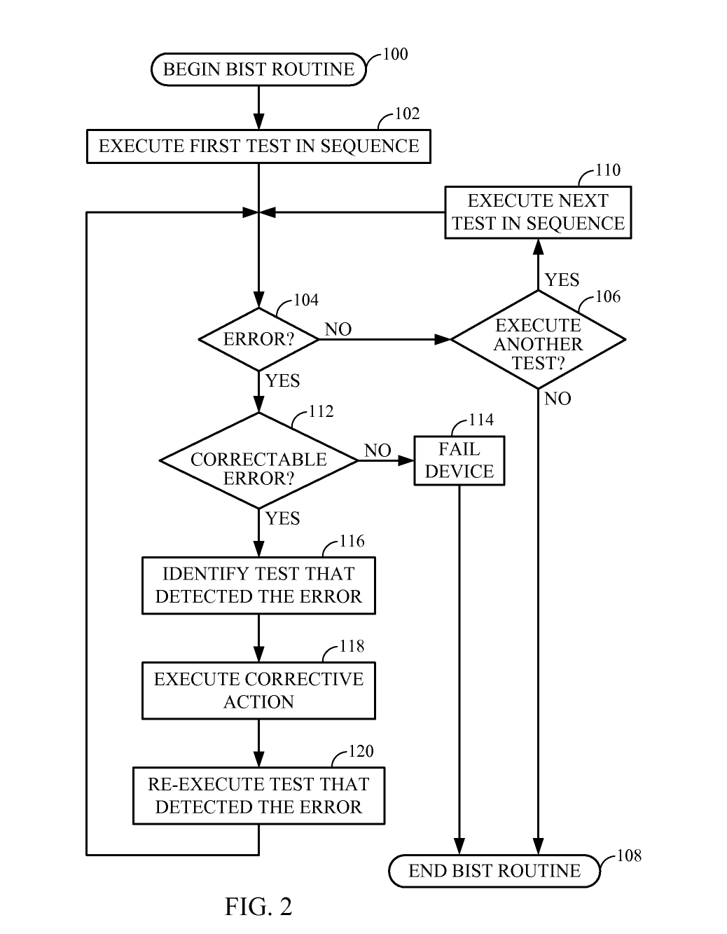

FIG. 2 illustrates one embodiment of program logic that may be implemented by the BIST engine 10 for executing a BIST routine. The program logic ‘begins’ with the BIST engine 10 beginning a new BIST routine, e.g., in response to an external signal (TEST) prompting a BIST routine (Step 100). As part of the BIST routine, the BIST state machine 12 initiates execution of a sequence of tests by providing a first test in the sequence to a circuit under test, where the circuit under test executes the test (Step 102). The response analyzer 16 then determines whether the circuit's response matches an expected response (Step 104). If no error is detected, the state machine 12 determines whether the entire sequence of tests has been executed in its entirety without error or whether the BIST routine is to be aborted (Step 106). If either condition is satisfied, the state machine 12 ends the BIST routine (Step 108). However, if additional tests are to be executed, the state machine 12 provides the next successive test in the sequence to the circuit under test, where the circuit under test executes the test (Step 110).

If the response analyzer 16 determines that a test detected an error, either the BIST engine 10 or the circuit under test determines whether the error is correctable, e.g., by determining whether a corrective action can be taken to correct the error (Step 112). If the error is not correctable, the BIST engine 10 identifies the circuit as a fail (Step 114) and then ends the routine (Step 108). If the error is correctable, the identity of the test that detected the error is noted (Step 116). In one embodiment, the identity, e.g., an index or ID uniquely associated with the test that detected the error is stored in the storage element 18. The corresponding corrective action is then taken (Step 118). In some embodiments, the BIST routine may be suspended while the corrective action is taken. In other embodiments, the BIST routine may continue executing to identify other errors while the corrective action is being taken. In either case, when the corrective action is completed, the BIST state machine 12 re-initiates execution of the test sequence starting with the test having the highest re-ordered priority, e.g., the test that detected the error corresponding to the corrective action just completed (Step 120). In one embodiment, the state machine 12 causes the storage element 18 holding test identifier information to be accessed. The most recently stored test identifier is retrieved, which corresponds to the corrective action most recently taken. The state machine 12 is thus able to identify the test that caused the most recent corrective action to be taken. As a result, instead of re-initiating execution of the test sequence starting in the original test execution order, the test that triggered the most recent corrective action is executed first (or a related test). That is, the BIST state machine 12 executes first the test indicated by the identifier retrieved from the storage element 18. The BIST routine continues until aborted or until the entire sequence of tests is executed in its entirety without detecting an error (see Step 106).

A device under test is declared ‘good’ when the entire sequence of tests is executed in its entirety without detecting an error. For this reason, re-initiating execution of a test sequence with the test having the highest re-ordered priority each time a corresponding corrective action is taken provides a substantial BIST efficiency improvement over conventional BIST routine execution methods. The efficiency improvement becomes appreciable when at least two corrective actions are taken during a BIST routine. The efficiency improvement increases substantially as the number of corrective actions taken increases. In addition to how many tests detect a fail, where those tests are located in the original sequence of tests also determines the amount of BIST efficiency improvement. That is, the deeper a test is located within an ordered sequence of tests, the more BIST efficiency improves in the event the test detects a correctable error. An illustration is provided next to better highlight the BIST efficiency improvements gained by executing BIST routines in accordance with the embodiments described herein. The following examples are for illustrative purposes only and in no way should be construed as limiting.

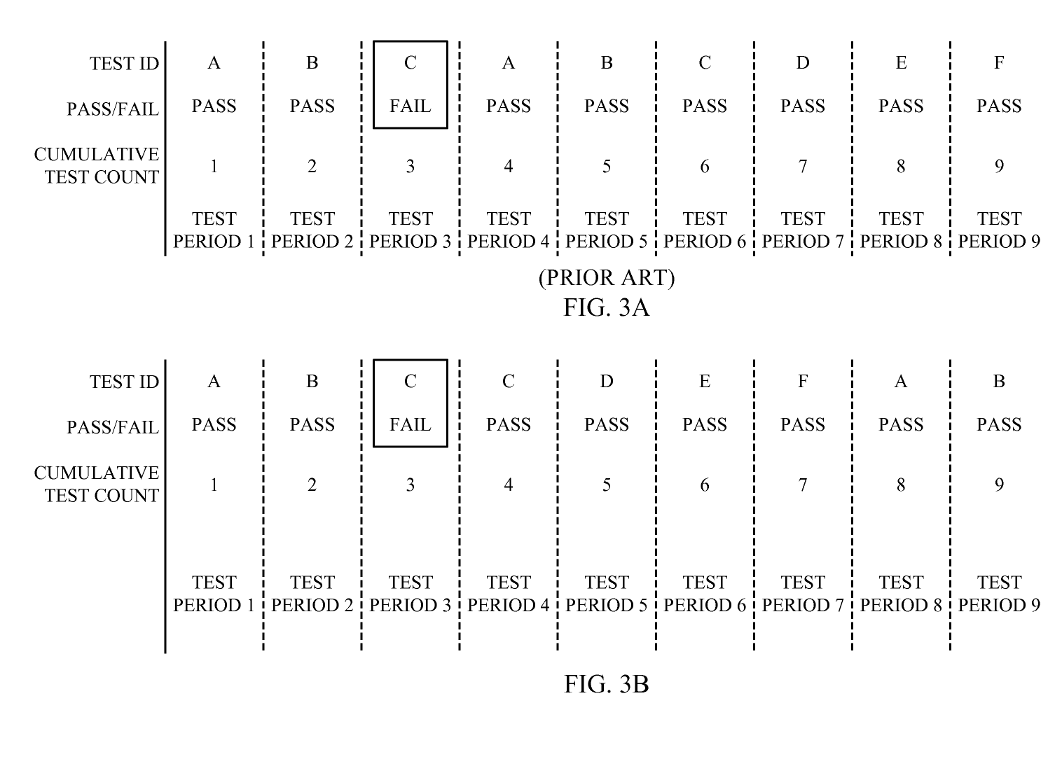

FIGS. 3A and 3B illustrate a first example where one test (C) in a sequence of six tests (A-F) detects a correctable error that triggers a corrective action. Recall, the device under test is deemed good after the test sequence is executed in its entirety without a fail. With this in mind, FIG. 3A illustrates the conventional approach for re-initiating execution of the test sequence after the corrective action is completed by starting with the test originally ordered first (test A). As can be seen from FIG. 3A, the number of tests re-executed (T_{RE}) before the device under test is deemed good corresponds to the Test Index (TI) of the test that detected the sole correctable error as given by:

T_{RE}=TI_{C} (1)

where test C is the third test in the sequence, thus TI_{C}=3. As a result, the conventional approach consumes nine BIST test periods in the present example, where each BIST test period corresponds to the amount of time consumed executing a particular test.

FIG. 3B illustrates how the BIST engine 10 described herein re-initiates execution of the test sequence after the corrective action is completed by starting with the test that detected the fail (test C). Particularly, after the corrective action has completed, the BIST state machine 12 causes the identifier associated with test C to be retrieved from the storage element 18. The state machine 12 then re-initiates execution of the test sequence starting with test C—the test that detected the sole correctable error. As can be seen from FIGS. 3A and 3B, the same quantity of tests (nine) are re-executed before the device under test is deemed ‘good’ regardless of the approach used. As such, when a single correctable error is detected, no appreciable BIST efficiency difference exists between the embodiments described herein and conventional approaches.

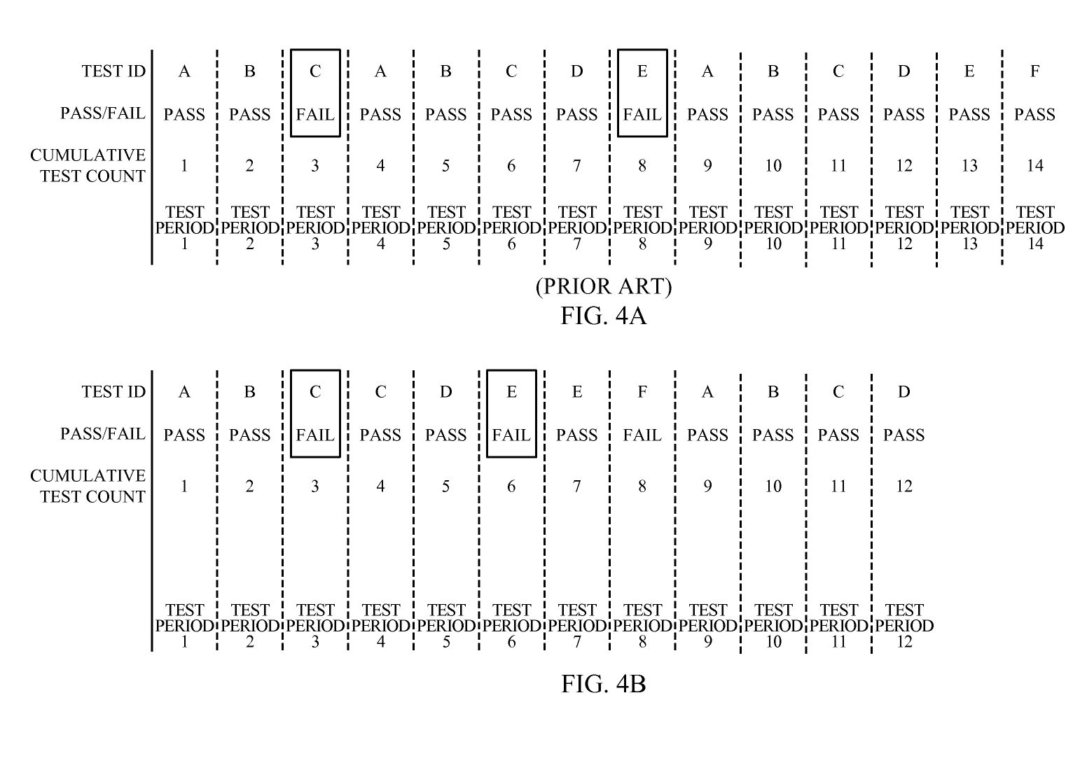

However, FIGS. 4A and 4B illustrate a second example where two tests (C and E) in the sequence of six tests (A-F) each detect a correctable error that triggers a respective corrective action. In this example, the BIST efficiency improvement provided by the embodiments described herein becomes readily apparent. FIG. 4A illustrates the conventional approach where execution of the test sequence is re-initiated after each corrective action is taken by starting with the test originally ordered first in the sequence (test A). As such, the test sequence begins re-execution in the same, original order each time a corrective action completes regardless of which test detected an error. That is, the test sequence is re-executed starting with test A after a corrective action corresponding to test C is completed and is then re-executed again starting with test A after a corrective action corresponding to test E is completed. Thus, the conventional approach re-executes eight tests as given by:

T_{RE}=TI_{C}+TI_{E} (2)

where test C is the third test in the sequence (thus TI_{C}=3) and E is the fifth test in the sequence (thus TI_{C}=5). The eight tests re-executed are A (twice), B (twice), C (twice), D (once) and E (once). As a result, the conventional approach consumes fourteen total BIST test periods in the present example.

FIG. 4B illustrates how the BIST engine 10 described herein re-initiates execution of the test sequence by starting with the test that detected the most recent fail. Particularly, when the corrective action associated with test C has completed, the BIST state machine 12 causes the identifier associated with test C to be retrieved. The state machine 12 then re-initiates execution of the test sequence starting with test C—the test that detected the first correctable error. Test execution then successively continues with test D until test E detects a second correctable error. When the corrective action associated with test E has completed, the BIST state machine 12 causes the identifier associated with test E to be retrieved. The state machine 12 then re-initiates execution of the test sequence starting with test E—the test that detected the most recent correctable error. Thus, each time execution of the test sequence is re-initiated after a corrective action has completed, the BIST state machine 12 starts with the test that detected the most recent error. As such, the state machine causes only six tests to be re-executed as given by:

$$\begin{matrix}{T}_{RE} = {TI}_{C} + [ ( {TI}_{E} - {TI}_{C} ) + 1 ] \\ = {TI}_{E} + 1\end{matrix} \qquad ( 3 )$$

where the six tests re-executed are A (once), B (once), C (twice), D (once) and E (once). As a result, only twelve BIST test periods are consumed as compared to fourteen with the conventional approach.

In general, BIST efficiency improvement (BIST_{eff}) as measured by the reduction of unnecessarily re-executed tests during a BIST routine is given by:

$${BIST}_{eff} = {\sum }_{i = 1}^{n - 1} {TI}_{i} - ( n - 1 ) \qquad ( 4 )$$

where n corresponds to the total number of detected errors. As directly evident from equation 4 and as exemplified in Table 1 below, BIST efficiency improvement depends on the number of detected correctable errors (n) as well as the depth or position of the tests that detected the errors within the original test sequence (as captured by the test index TI). That is, the deeper a test is located within a test sequence, the greater the improvement in BIST efficiency if that test detects an error. Although not directly apparent from equation 4, BIST efficiency is further dependent upon the length of tests whose re-execution is avoided by the state machine 12 during a BIST routine. That is, the longer a test takes to execute, the more time saved by not unnecessarily re-executing that test.

TABLE 1
Example of BIST Efficiency Improvement

| | | Number of Tests | |
|---|---|---|---|
| Number of | Number of Tests | Re-executed | |
| Detected | Conventionally | According to the | |
| Errors | Re-executed | Present Invention | BIST_{eff} |
| 1 | TIₑᵣᵣₒᵣ₁ | TIₑᵣᵣₒᵣ₁ | 0 |
| 2 | TIₑᵣᵣₒᵣ₁ + TIₑᵣᵣₒᵣ₂ | TIₑᵣᵣₒᵣ₂ + 1 | TIₑᵣᵣₒᵣ₁ − 1 |
| 3 | TIₑᵣᵣₒᵣ₁ + TIₑᵣᵣₒᵣ₂ + TIₑᵣᵣₒᵣ₃ | TIₑᵣᵣₒᵣ₃ + 2 | TIₑᵣᵣₒᵣ₁ + TIₑᵣᵣₒᵣ₂ − 2 |
| n | ${\sum }_{i = 1}^{n} TIi$ | TIₑᵣᵣₒᵣₙ + (n − 1) | ${\sum }_{i = 1}^{n - 1} TIi - ( n - 1 )$ |

In one embodiment, tests executed by the BIST engine 10 are generated external to the BIST engine 10, e.g., by equipment such as an external tester. In another embodiment, the tests are generated by the test pattern generator 14. To that end, the test pattern generator 14 may comprise any suitable hardware for generating BIST-based test patterns such as a Feedback Shift Register (FSR), a Linear FSR (LFSR), counters or other circuitry capable of generating test patterns and/or non-volatile memory (not shown) such as Read Only Memory (ROM) for storing test patterns. Regardless, the tests may be exhaustive, pseudo-exhaustive, random, and/or pseudo-random in nature.

Tests executed during a BIST routine are designed to detect errors in the circuitry being tested, e.g., a hard fault having a permanent failure signature or a soft fault having an intermittent failure signature. In response to a detected correctable error, the device being tested, or alternatively, the BIST engine 10, initiates a corresponding corrective action as previously described. The corrective action is designed to correct the detected fault. For example, if the circuit under test is a memory device, a redundant array line may replace the failing array line, e.g., using a fuse blow mechanism. Similarly, failing logic circuits may be replaced with available redundant circuit elements. For soft failure mechanisms, an operating parameter causing the error may be adjusted in attempt to correct an error. For example, a critical path in the circuit under test may fail a timing margin. A corrective action may involve lowering the operating frequency of the device being tested, lowering the operating temperature, increasing the operating voltage, or some combination thereof.

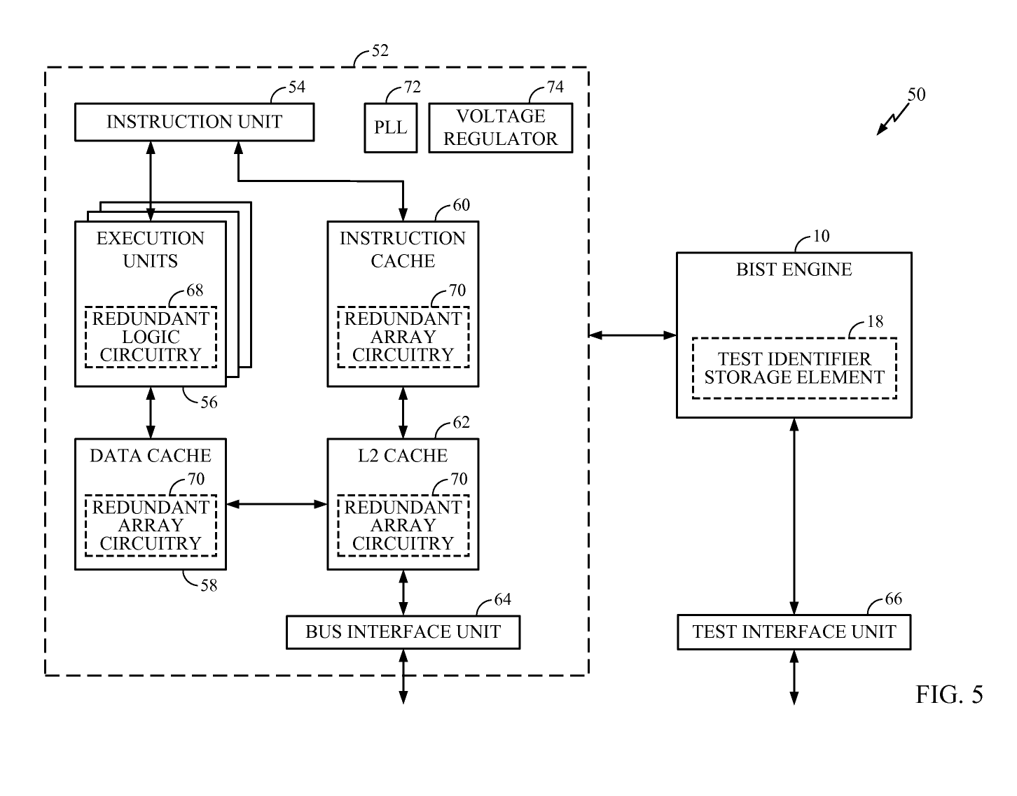

Regardless, the BIST engine 10 described herein may be included in any device capable of self-test. In one embodiment, the BIST engine 10 is included in a microprocessor 50, as illustrated in FIG. 5. The microprocessor 50 embodiment is presented as a non-limiting example illustrating the inclusion of the BIST engine 10 in an integrated circuit. Those skilled in the art will readily recognize that the BIST engine 10 disclosed herein may be included in any device having self-test capability such as memory devices, digital signal processors, analog integrated circuits, mixed-signal integrated circuits, application-specific integrated circuits, etc.

In addition to the BIST engine 10, the microprocessor 50 also includes functional circuitry 52. The functional circuitry 52 implements the processing functions supported by the microprocessor 50. Among other components, the functional circuitry 52 includes an instruction unit 54, one or more execution units 56, first-level data and instruction caches, 58, 60, a second-level cache (L2 cache) 62, and a bus interface unit 64. The instruction unit 54 provides centralized control of instruction flow to the execution units 56. The execution units 56 execute instructions dispatched by the instruction unit 54. The data and instruction caches 58, 60 store data and instructions, respectively. The L2 cache 62 provides a high-speed memory buffer between the data and instruction caches 58, 60 and memory (not shown) external to the microprocessor 50 while the bus interface unit 64 provides a mechanism for transferring data, instructions, addresses, and control signals to and from the microprocessor 50.

The BIST engine 10 tests the functional circuitry 52 of the microprocessor 50 for faults by executing a sequence of tests designed to identify errors. Signals that control the setup and operation of the BIST engine 10 as described herein may be communicated to the microprocessor 50 via a dedicated test interface unit 66, e.g., an IEEE 1149.1 Joint Test Access Group (JTAG) compatible test interface. Alternatively, the microprocessor bus interface unit 64 may be used to receive such signals. Regardless, the BIST engine 10 may be designed to test various components of the functional circuitry. For example, the BIST engine 10 may execute logic-based BIST routines for testing the instruction unit and the execution units 54, 56. The BIST engine 10 may further execute memory-based BIST routines for testing the caches 58-62, e.g., BIST routines for testing a random access memory portion and a content addressable memory portion (both not shown) of the caches 58-62. Other routines may be executed by the BIST engine 10 depending on the integrated circuit type, e.g., analog and mixed-signal based BIST routines. Tests provided by the BIST engine 10 may be delivered to the functional circuitry 52 and corresponding circuit responses received from the circuitry 52 via any suitable mechanism such as scan chains or a dedicated test bus (both not shown).

Further, various components included in the functional circuitry 52 may have corresponding redundant components. For example, one or more of the execution units 56 may have a corresponding logic redundancy circuit 68 included in or associated with the execution units 56. In addition, the caches 58-62 may also have corresponding redundant components, e.g., redundant array circuitry 70 included in or associated with the caches 58-62. The redundant circuitry 68, 70 may be arranged and grouped in various configurations, any suitable arrangement and configuration being within the scope of the embodiments discussed herein. In one embodiment, a corrective action involves replacing a faulty circuit component with a corresponding redundant element 68, 70.

In addition to circuit redundancy, the microprocessor 50 may also be capable of adjusting one or more operating parameters such as frequency, voltage and indirectly temperature in an attempt to mitigate errors detected by the BIST engine 10. In one embodiment, a corrective action involves adjusting the clock output from a Phase-Locked-Loop (PLL) 72 included in the microprocessor 50, e.g., by adjusting a feedback loop (not shown) of the PLL 72. In another embodiment, a corrective action involves adjusting one or more power supply levels output by a voltage regulator 74 included in the microprocessor 50.

Regardless of the nature of corrective actions available to the microprocessor 50, the BIST engine 10 controls execution of BIST routines designed to test the functional circuitry 52 of the microprocessor 50 as previously described. When a test detects a correctable error, a corresponding identifier is stored in the storage element 18. The storage element 18, from which the test identifiers are subsequently retrieved by the BIST engine 10, may be included in the BIST engine 10 or included in the functional circuitry 52 of the microprocessor 50. Each time a corrective action is taken during a BIST routine, the BIST engine 10 re-initiates execution of the test sequence starting with the test identified as having the highest re-ordered priority. In doing so, BIST efficiency is greatly improved by eliminating unnecessary re-execution of certain tests.

With the above range of variations and applications in mind, it should be understood that the present invention is not limited by the foregoing description, nor is it limited by the accompanying drawings. Instead, the present invention is limited only by the following claims and their legal equivalents.

What is claimed is:

1. A method of executing a built-in self-test (BIST) routine, comprising:
initiating execution of a sequence of tests configured to detect errors; and
after a corrective action is taken in response to one or more of the errors being detected, re-initiating execution of the sequence of tests starting with the test that detected the error corresponding to the corrective action most recently taken.

2. The method of claim 1, further comprising ending the BIST routine after the entire sequence of tests is re-executed without detecting an error.

3. The method of claim 1, further comprising ending the BIST routine in response to the sequence of tests being aborted.

4. The method of claim 1, wherein the corrective action comprises at least one of enabling a redundant circuit and adjusting an operating parameter.

5. The method of claim 4, wherein the redundant circuit comprises one of a redundant memory circuit, a redundant logic circuit, a redundant analog circuit and a redundant mixed-signal circuit.

6. The method of claim 4, wherein the operating parameter comprises one of frequency, temperature and voltage.

7. The method of claim 1, wherein each error corresponds to one of a hard failure and a soft failure.

8. The method of claim 1, further comprising storing an identifier uniquely associated with the test that detected the most recent error.

9. The method of claim 8, wherein after a corrective action is taken in response to one or more of the errors being detected, re-initiating execution of the sequence of tests starting with the test that detected the error corresponding to the corrective action most recently taken comprises:
retrieving the identifier; and
re-initiating execution of the sequence of tests starting with the test indicated by the identifier.

10. A built-in self-test (BIST) circuit, comprising circuitry configured to initiate execution of a sequence of tests configured to detect errors and, after a corrective action is taken in response to one or more of the errors being detected, to re-initiate execution of the sequence of tests starting with the test that detected the error corresponding to the corrective action most recently taken.

11. The BIST circuit of claim 10, wherein the circuitry is further configured to end the BIST routine after the entire sequence of tests is re-executed without detecting an error.

12. The BIST circuit of claim 10, wherein the circuitry is further configured to end the BIST routine in response to the sequence of tests being aborted.

13. The BIST circuit of claim 10, wherein the corrective action comprises at least one of circuit redundancy and operating parameter adjustment.

14. The BIST circuit of claim 10, wherein each error corresponds to one of a hard failure and a soft failure.

15. The BIST circuit of claim 10, wherein the circuitry is further configured to direct storage of an identifier uniquely associated with the test that detected the most recent error.

16. The BIST circuit of claim 15, wherein the circuitry is configured to re-initiate execution of the sequence of tests starting with the test that detected the error corresponding to the corrective action most recently taken by directing retrieval of the identifier and re-initiating execution of the sequence of tests starting with the test indicated by the identifier.

17. An integrated circuit including the BIST circuit as claimed in claim 10.

18. A microprocessor including the BIST circuit as claimed in claim 10.

19. A method of executing a built-in self-test (BIST) routine, comprising:
initiating execution of a sequence of tests; and
after a corrective action is taken, re-initiating execution of the sequence of tests starting with the test having a highest re-ordered priority.

20. A computer program product for directing execution of a built-in self-test routine in an integrated circuit, comprising:
program code for initiating execution of a sequence of tests; and
program code for re-initiating execution of the sequence of tests after a corrective action is taken starting with the test having a highest re-ordered priority.

21. The computer program product of claim 20, wherein the program code for re-initiating execution of the sequence of tests after a corrective action is taken starting with the test having a highest re-ordered priority comprises program code for directing retrieval of an identifier uniquely associated with the test having the highest re-ordered priority and re-initiating execution of the sequence of tests starting with the test indicated by the identifier.
